(19) United States
(12) Patent Application Publication
(10) Pub. No.: US 2009/0236942 A1
(43) Pub. Date: Sep. 24, 2009

(54) Device with electroceramic/and variant/ and way of using the device with electroceramic/and variant/

(76) Inventor: Vladimir Ivanovich Ivanov, Brooklyn, NY (US)

Correspondence Address: Vladimir Ivanovich Ivanov, PMB 143, 7822 20th ave, Brooklyn, NY, 11214, US

(21) Appl. No.: 11/263,377

(22) Filed: May 15, 2006

(51) Int. Cl. H01L 41/053; H01L 41/047

(52) U.S. Cl. 310/348; 310/317

(57) ABSTRACT

The device with electroceramic/and variant/ and way of using the device with electroceramic/and variant/.

The invention is from the field of technic which electroceramic is used in.

The device with electroceramic has an element made of electroceramic, elements made conducting energies. Elements made conducting energies are connected with the elements made of electroceramic.

The device with electroceramic is in a frame.

Constructive features of the claimed invention give an opportunity of exciting the element made of piezoelectric.

Constructive features of the invention give an opportunity of effective use of elements made of electroceramic.

The claimed invention is simple in construction, comfortable and economical in use and doesn't take much time to be prepared for the work.

The invention is of the field of technic, its means of technic which electroceramic is used in.

This invention can also be used with equipment for creating a possibility of receiving and transmitting of information/including reception of information during medical examination with ultrasound diagnostic system/, processing of different materials, destroying tumors and concrements, used in accelerometers, detonators, photoflash starters, earphones, hearing aids, cordial pumps, buzzers, loudspeakers/highfrequency/, machine drives, electromechanic locks, chemical processors/emulsifies, polymerizers, sterilizers, and soon/, in piezoelectric sensors in automatics and telemechanic, electromechanical conventers/ for example, microphones, telephones, hydrophones/, ultrasound viding, delay lines, filters, exciters transformators, devices on surface acoustic waves and so on.

Are known piezoelectric conventers, piezoconventers of electric waves in mechanical and vice versa.

A short-coming of the analogue is issuficient effectiveness of appearing the direct and feed-back piezoelectric effects impossibility of using widely.

Is also known a piezoelement/a part made of piezoelectric material with electrodes/analogue/.

A short coming of the analogue is impossibility of functioning as liquid crystals of piezoelectric and electrodes don,t allow to insure a reliable effects of appearing of direct and feedback piezoelectric effects.

Are known piezoelectric materials, analogue/Encyclopedic dictionary on physics, v.4, publisher “Sovetskaya encyclopedia”, p.251/.

A short-coming of the analogue is that of appearing of conditioning of its using if necessary constructive form with insuring direct and feed-back piezoelectric effects.

Are known piezoelectric, prototype, crystal dielectric which are able to be polarized under influence of mechanic strains/direct piezoelectric effects/ and be determined under the implied outer field/feed-back piezoelectric effects/,Electronic, “Encyclopedia slovar, Moscow, Sovetskaya encyclopedia, 1991, p. 444.

A short-coming of the prototype is insufficient effectiveness in insuring direct and feed-back piezoelectric effects. Moreover,a short-coming of the prototype is, that it cannot be used, as other electroceramic.

Purpose of this invention was creation of a device with electroceramic/ and variant/ which enables during its use to get an opportunity of effective using of electroceramic.

The put goal is achieved, that in the device with electroceramic according to the invention, the device with electroceramic/variant/ is in a frame.

The put goal is achieved, that in the device with electroceramic/variant/, according to the invention, with the element made of electroceramic are connected elements made conducting energies.

The put goal is achieved, that according to the way of use of the device with electroceramic/and variant/, according to the invention, the device with electroceramic/and variant/ is used with maximum elimination of all the hindering factors.

Moreover, the device with electroceramic/and variant/ is used by connection.

Moreover, the device with electroceramic/and variant/ connection is made.

Such a form of the patented with electroceramic/and variant/:

a/ insures possibility of effective using elements made of electroceramic;

b/ insures possibility of appearance of direct and feed-back pie zoelectric effects if necessary;

c/ insures possibility of implying energy of electroceramic;

d/ ensures possibility of implying energy of electroceramic;

e/ ensures reliable acoustic contact of the device with electroceramic if necessary with the help of elements made of piezoelectric in the device with electroceramic;

f/ it is simple in construction, long-lasting, economical in use and doesn,t take much time to be prepared for work.

On the drawings are showed variants of the claimed invention:

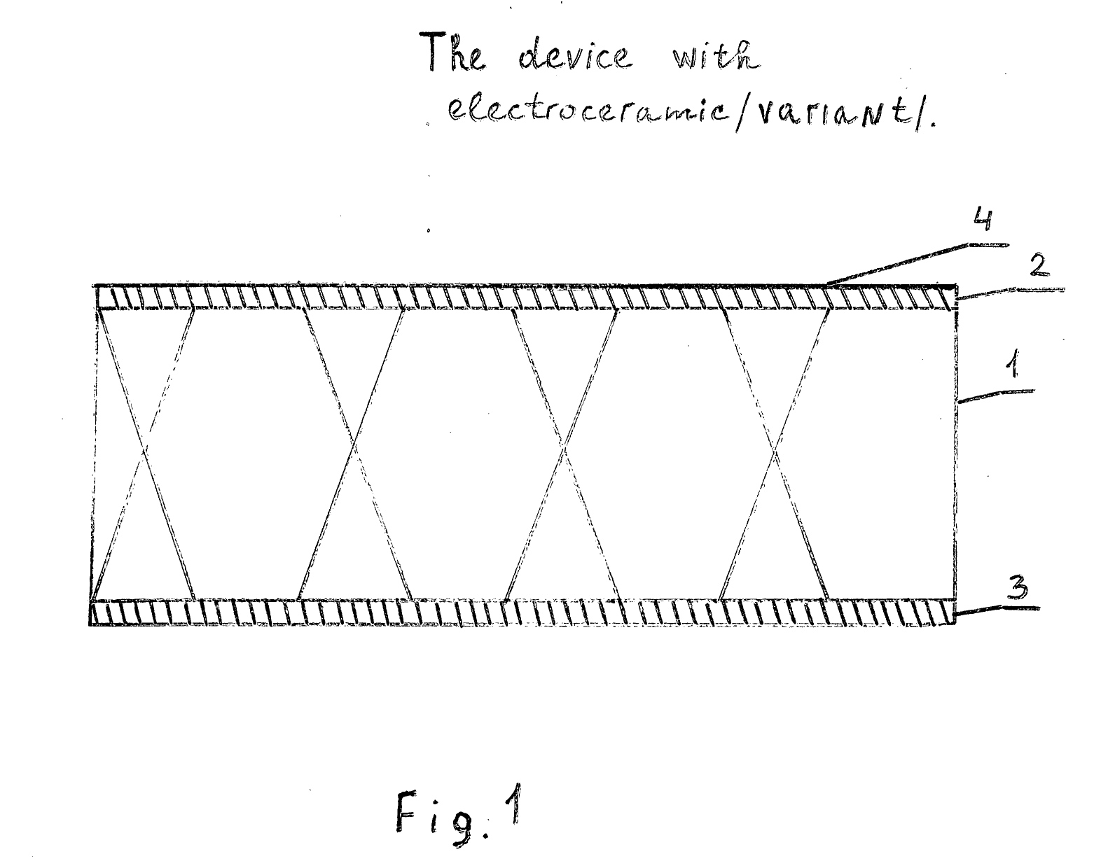

On FIG. 1 “The device with electroceramic”/variant/ has element 1 made of electroceramic and elements 2 and 3 made conducting energies connected with element 1 made of electroceramic. Element 2 made conducting energies has contact surface 4.

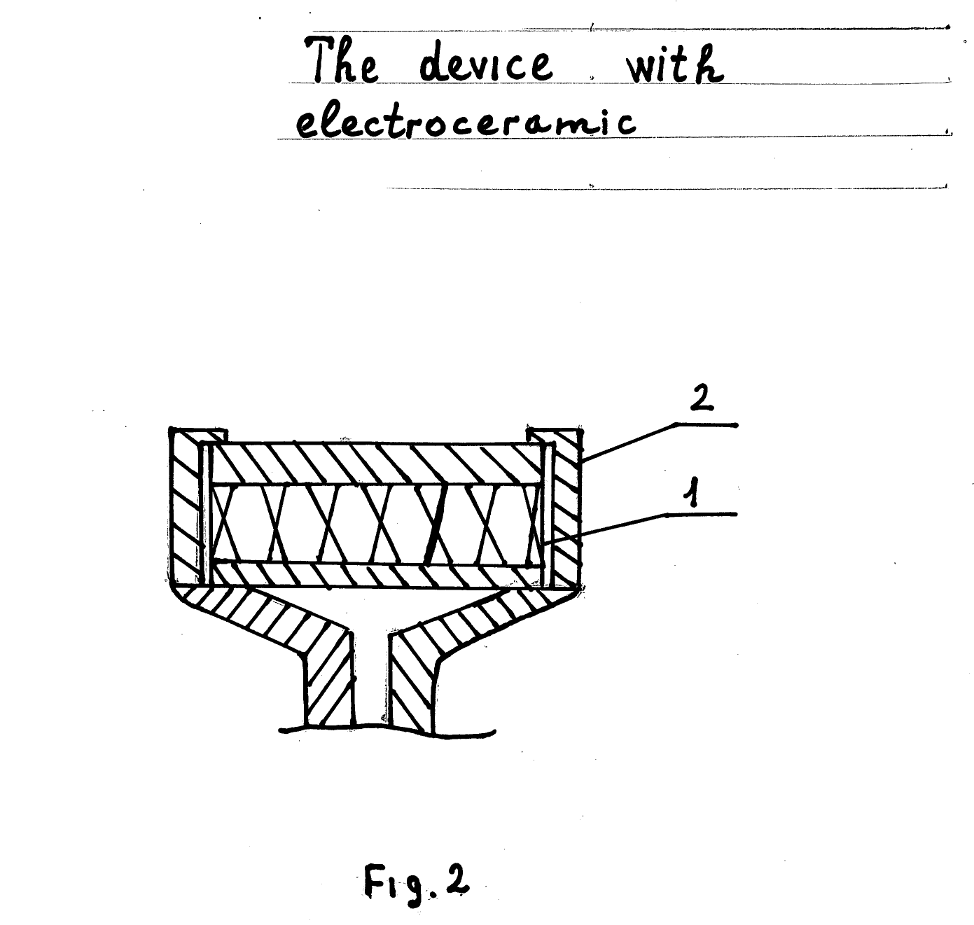

On FIG. 2 “The device with electroceramic” has a device with electroceramic/variant/ 1/accordingly to FIG. 1/ which is in the frame 2.

“the device with electroceramic”/and variant/ is used the following way: the device with electroceramic/variant/, according to FIG. 1, with maximum elimination of all the hindering factors, put/if necessary/ in a frame/FIG. 2/. Element 1 made of electroceramic /of piezoelectric-variant of use in this variant of use/ of the device with electroceramic/and variant/, accordingly to FIG. 1-2, is connected/with maximum elimination of all the hindering factors/ with the help of elements/a accordingly to FIG. 1-2/ 2 and 3/with equipment used on its purpose/not shown on FIG. 1/ for example with miliampermeter.

After connection/with maximum elimination of all the hindering factors/ the contact surface/according to FIG. 1/ with a power source exciting element made of electroceramic/of piezoelectricvariant of use, in this variant of use, according to FIG. 1-2 1/ is implied with energy. Then/on appearing of direct piezoelectric effect of element 1 made of electroceramic/of piezoelectric variant of use/ energy of excited element 1 made of electroceramic/e to the eat to be treated. On patient head is put a headband with a hinge/lock for fixing ultrasound emitter/. In the outer hearing duct to be treated is poured 0.5 ml medical preparation kavinton/which replaces air out of the outer hearing duct. On the hinge lock of the headband the ultrasound emitter is put. Then on the contact surface of the ultrasound emitter is put a drop of kavint on replacing and removing maximally all the factors hindering spreading of ultrasound waves from the contact surface of the ultrasound emitter, emitting ultrasound waves during working of ultrasound emitter, to be influenced with ultrasound waves. Then ultrasound emitter is fixed on the hinge lock of the headband and is put in to the outer hearing duct. Then generator of ultrasound waves is switched on and the procedure of ultrasoundphoresis with kavinton is conducted in the mode of ultrasound waves intensity of 0.05 w/cm,in constant mode of ultrasound with frequency of 880 kHz

After finishing the procedure the device for ultrasound therapy is switched off. The procedure of ultrasoundphoresis is over. During the procedure of ultrasoundphoresis the patient went through procedure of endoaural electrophoresis with kavinton on the same ear, this patient got a procedure of ultrasoundelectrophoresis. After treatment the headband with hinge lock with the ultrasound emitter was removed from the patient head and the indifferent electrode was also removed. After 10 conducted treatment of ultrasoundelectrophoresis with kavinton/once a day on a car, on both ears in turn/. Simultaneous with procedures of ultrasoundelectrophoresis with kavinton the patient felt no improvement, noise in ears reduced.

Features of construction of the claimed invention enable during its use to ensure a possibility of appearing/when being used/ of direct and feed-back piezoelectric effect. The claimed invention ensures possibility of effective use of elements made of electroceramic ensures influence of energy of electroceramic. The claimed invention ensures when being used with piezoelectric a reliable acoustic contact of the device with to be influenced with ultrasound waves.

The claimed invention is easy in construction, construcing, longlasting, economical in use, doesn,t require much time to be prepared for work.

Author:

Information Sources:

1. Encyclopedia dictionary on physics, v.4, publisher “Sovetskaya encyclopedia”, p. 251.

### Formula of the Invention

1. The device with electroceramic, containing the device with electroceramic/variant/, differing in, that for the purpose of effective functioning of the device with electroceramic/variant/, the device with electroceramic/variant/ is in a frame.

2. The device with electroceramic/variant/, containing the element made of electroceramic, differing in, that for the purpose of effective functioning of the element made of electroceramic, with the element made of electroceramic are connected elements conducting energies.

3. Way of using the device with electroceramic/and variant/, including using element made of electroceramic, differing in, that for the purpose of effective functioning of the device with electroceramic/and variant/, the device with electroceramic/and variant/ is used with maximum possible elimination of all the hindering factors.

4. Way of using the device with electroceramic/and variant/, according to clause 3, differing in, that the device with electroceramic/and variant/ is used by connection.

5. Way of using the device with electroceramic/and variant/, according to claused 3-4, differing in, that with the device with electroceramic/and variant/ a connection is made.

Author: /V. I. Ivanov/.

Information sources:

1. Materials of International Conference of Electroceramic 04 19 98, 06.1998.

2. Materials of European Conference on polar dielectrics. 29.11.1 999; 04. 1998.

3. Materials of International Symposium on ferroelectrics. 11.199 8; 26.11.2000.

Formula of invention:

1. The device with electroceramic, containing the device with electroceramic/variant/, differing in, that for the purpose of effective functioning of the device with electroceramic/variant/, the device with electroceramic/variant/ is in a frame.

2. The device with electroceramic/variant/, containing the element made of electroceramic, differing in, that for the purpose of effective functioning of the element made of electroceramic, with the element made of electroceramic are connected elements conducting energies.

3. Way of using the device with electroceramic/and variant/, including using element made of electroceramic, differing in, that for toepurpose of effective functioning of the device with electroceramic/and variant/, the device with electroceramic/and variant/ is used with maximum possible elimination of all the hindering factors.

4. Way of using the device with electroceramic/and variant/, according to clause 3, differing in, that the device with electroceramic/and variant/ is used by connecting.

5. Way of using the device with electroceramic/and variant/, according to claused 3-4, differing in, that with the device with electroceramic/and variant/ a connection is made.
